(19) United States
(12) Patent Application Publication
(10) Pub. No.: US 2003/0151870 A1
(43) Pub. Date: Aug. 14, 2003

(54) Device for voltage transformation

(76) Inventors: Roman Gronbach, Korntal (DE); Joerg Jehlicka, Leonberg (DE)

Correspondence Address: KENYON & KENYON, ONE BROADWAY, NEW YORK, NY, 10004, US

(21) Appl. No.: 10/276,277

(22) PCT Filed: Feb. 16, 2002
(86) PCT No.: PCT/DE02/00573

(30) Foreign Application Priority Data
Mar. 14, 2001 (DE) 101 12 141.5

(51) Int. Cl. H03K 17/687; H02H 3/20; H02H 9/04

(52) U.S. Cl. 361/91.1; 327/427

(57) ABSTRACT

A device for voltage transformation of an input voltage into at least one output voltage is described, which includes at least one switching means (12), a freewheeling switching means (14), and an electrical energy accumulator (16, 18), the freewheeling switching means (14) being triggered for voltage transformation in normal operation. Monitoring means are provided for detecting when the output voltage exceeds a limit voltage, which trigger the freewheeling switching means (14) to limit the output voltage in the event the limit voltage is exceeded.

### BACKGROUND INFORMATION

The present invention is directed to a device for voltage transformation according to the definition of the species in the main claim. A circuit system for transforming an input voltage into an output voltage is known from German Patent Application 198 39 445 A1. It includes a first circuit, which has a switching transistor, a first inductor, and a component acting as a freewheeling diode, a first capacitor being connected in parallel to this component. A second circuit forms a loop between an input side and output side of the switching transistor and has a second capacitor, a diode, a second inductor, and a third capacitor. This circuit represents a multi-resonant transformer circuit having multiple resonance frequencies which is easily controllable, using PWM in particular.

The present invention is based on the object of providing a device for voltage transformation which, at a low additional cost, is suitable for limiting overvoltage at the output of the voltage transformer. This object is achieved by the features of the main claim.

### ADVANTAGES OF THE INVENTION

The device according to the present invention for voltage transformation, which transforms an input voltage into at least one output voltage, includes at least-one switching means, a freewheeling switching means, and at least one energy accumulator. In normal operation, the freewheeling switching means is activated for voltage transformation. According to the present invention, means are provided, for detection of a limit voltage being exceeded by the output voltage, which, in the event the limit voltage is exceeded, trigger the freewheeling switching means to limit the output voltage. In particular in the event of a short-circuit between the input voltage and the output voltage, the possibility must be provided to protect the low-voltage consumer in the event of a short circuit, for example through voltage limiting in the event of a short circuit. This protective function may be implemented using only a few additional components by making use of the freewheeling switching means which are present in the DC/DC transformer in any case. Only means have to be provided which, in the event of the output voltage exceeding the limit voltage, trigger the freewheeling switching means in order to limit the voltage. Zener diodes and/or bipolar transistors are, for example, suitable for this purpose, which may be used to trigger the freewheeling switching means for voltage limiting at a specific limit voltage. These components are available at a low cost, so that the desired protective function may be implemented without a large cost increase. If similar components are used to detect when the permissible value of the output voltage is exceeded, the protective function may be triggered almost without a delay. This elevates the quality of the protective function.

The device according to the present invention for voltage transformation of an input voltage into at least one output voltage is preferably used in a dual-voltage vehicle electrical system of a motor vehicle. The effects of a possible short circuit from a 42 V vehicle electrical system to a 14 V vehicle electrical system are alleviated using the device according to the present invention.

Further expedient refinements result from further dependent claims and the description.

### DRAWING

Multiple exemplary embodiments of the device for voltage transformation according to the present invention are illustrated in the drawing and described in the following.

FIG. 1 shows a block diagram of a choke transformer having synchronous rectifying,

FIG. 2 shows a first trigger circuit having Zener diodes, and

FIG. 3 shows a second trigger circuit having a bipolar transistor.

### DESCRIPTION OF THE EXEMPLARY EMBODIMENTS

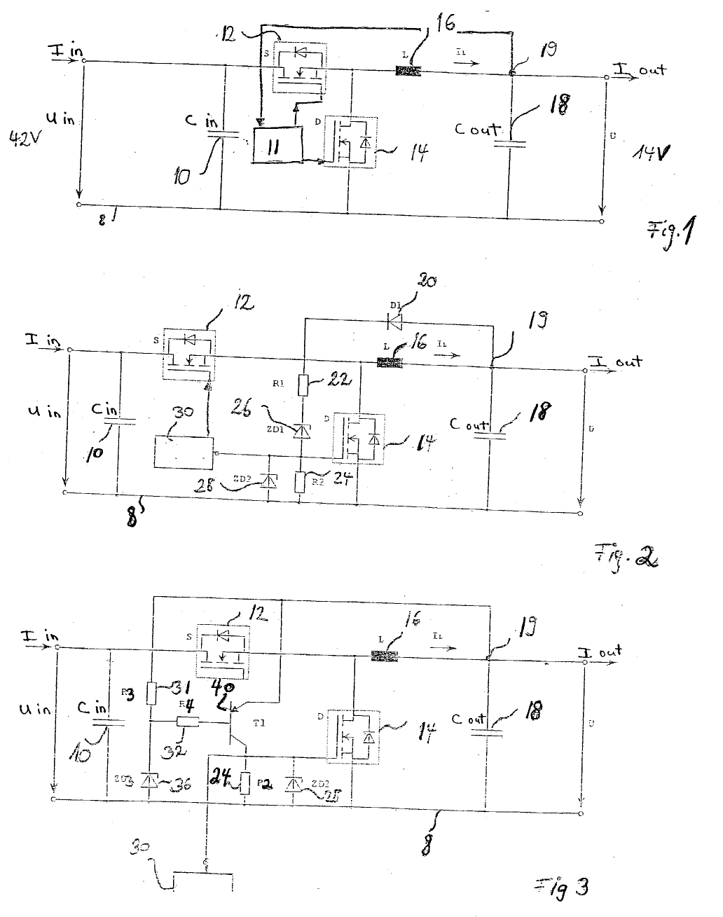

An input voltage Uin having associated input current Iin is connected in parallel using an input capacitor 10 and is transformed into an output voltage U. Input voltage Uin and input capacitor 10 are connected to a reference potential 8. Input current Iin reaches a junction point, which is connected to input capacitor 10 and to the drain terminal of a switching transistor 12. The source terminal of switching transistor 12 is connected to both the drain terminal of a freewheeling switching means 14 and to an accumulator choke 16. The other terminal of accumulator choke 16 is in contact with a further junction point 19, at which an output capacitor 18 is connected to reference potential 8. The source terminal of freewheeling switching means 14 is at reference potential 8, and the gate terminal of freewheeling switching means 14 is controlled by a trigger circuit 11. Output capacitor 18 is connected in parallel to output voltage U and is connected to reference potential 8. The system sketched in FIG. 1 is a choke transformer having synchronous rectifying. Furthermore, a trigger circuit 11 is provided, which is used to trigger switching transistor 12 and freewheeling switching means 14. Trigger circuit 11 is supplied the output potential of output voltage U.

According to the exemplary embodiment shown in FIG. 2, output voltage U is tapped at output node 19 and supplied to a first Zener diode 26 via a first diode 20 and a first resistor 22. In order to protect freewheeling switching means 14 from overvoltages and overcurrents, the gate terminal of freewheeling switching means 14 is connected, via a parallel circuit made up of a second Zener diode 28 and a second resistor 24, to reference potential 8. A gate driver 30 triggers the gate terminals of switching transistor 12 and freewheeling switching means 14. Otherwise, this design does not differ from that of FIG. 1.

In the exemplary embodiment shown in FIG. 3, output voltage U is supplied, via a third resistor 31 and a fourth resistor 32, to the base of a bipolar transistor 40. The emitter of transistor 40 is at the same potential as output node 19. The collector of transistor 40 is connected to the gate terminal of freewheeling switching means 14. As already described for the exemplary embodiment shown in FIG. 2, second resistor 24 and second Zener diode 28 are used as overvoltage and overcurrent protection for freewheeling switching means 14, connected in parallel between the gate terminal and reference potential 8. The shared potential of third resistor 31 and fourth resistor 32 reaches the cathode of a third Zener diode 36, whose anode is connected to reference potential 8. Gate driver 30 also triggers the gate terminal of freewheeling switching means 14.

The DC/DC transformer is preferably used in a dual-voltage vehicle electrical system (for example 42 V/14 V) of a motor vehicle. In the event of a short circuit between these two voltage levels, the short-circuit voltage of the 14 V vehicle electrical system is to be limited to 27 V, for example. For this purpose, freewheeling switching means 14 of the normal operation (DC/DC transformation) is used, in combination with an overvoltage detector, for voltage limiting.

In normal operation, input voltage Uin of, for example, 42 V is to be transformed into an output voltage U of, for example, 14 V. If switching transistor 12 is switched on and freewheeling switching means 14 is simultaneously switched off, an increasing current flows through accumulator choke 16. In the next cycle, switching transistor 12 is switched off and freewheeling switching means 14 is simultaneously switched on. Accumulator choke 16 functions as a current store and charges output capacitor 18 via freewheeling switching means 14. Subsequently, switching transistor 12 is reactivated and freewheeling switching means 14 is deactivated and so on. The degree of voltage transformation may be set via the pulse width ratio (switched-on time of switching transistor 12 in relation to a fixed period). The electrical losses in normal operation may be minimized by using a MOSFET transistor (having an integrated inverse diode), which is illustrated in the figures, as freewheeling switching means 14.

If output voltage U exceeds a preselectable voltage level of, for example, 27 V, trigger circuit 11 detects this with the aid of Zener diodes 26, 36 and causes freewheeling switching means 14 to no longer operate in normal operation, but rather to be used for limiting output voltage U. Freewheeling switching means 14 is triggered linearly in output voltage limiting operation in such a way that a current flow to reference potential 8 arises via accumulator choke 16. Overvoltage U, which may damage the 14 V consumer, is dissipated via accumulator choke 16, freewheeling switching means 14, and reference potential 8, which is typically ground.

Trigger circuit 11 is shown in more detail in FIG. 2. In normal operation, freewheeling switching means 14 operates as described in connection with FIG. 1. Freewheeling switching means 14 is triggered to form a loop for voltage limiting operation only when output voltage U exceeds a specific voltage level. First Zener diode 26 monitors the output voltage for exceeding the limit voltage. If the gate of the transistor implementing freewheeling switching means 14 is discharged and output voltage U exceeds the Zener voltage of first Zener diode 26, freewheeling switching means 14 is triggered until output voltage U reaches approximately the value of the Zener voltage of first Zener diode 26. In the case of overvoltage of output voltage U, gate driver 30 is to be switched to high resistance, so that it does not influence the limiting circuit. In other words, gate driver 30 no longer carries out the pulse width modulated triggering in synchronization with switching transistor 12 which is typical in normal operation.

Freewheeling switching means 14 is protected from overvoltage through triggering by second Zener diode 28. Simultaneously, first resistor 22 limits the current through both Zener diodes 26, 28 to permissible values. In addition, first diode 20 prevents current flow from gate driver 30 into the vehicle electrical system in the event of a triggered state of freewheeling switching means 14 and a low output voltage U. Second resistor 24 ensures a defined discharge of the gate of freewheeling switching means 14 when the gate driver is at a high resistance and output voltage U is below the limiting value.

By using an active trigger circuit having a pnp transistor 40 as shown in FIG. 3, the sensitivity of voltage limiting may be significantly elevated. voltage limiting may be used in a significantly smaller voltage range than in the exemplary embodiment shown in FIG. 2. If output voltage U exceeds the Zener voltage of third Zener diode 36, a current flows via third resistor 31. The voltage drop produced across third resistor 31 triggers transistor 40. The base current amplified as a result causes freewheeling switching means 14 to be triggered. If output voltage U exceeds the limit voltage, gate driver 30 is also to be switched so it is high resistance in this case, in order to avoid mutual interference. In the event of freewheeling switching means 14 being triggered by gate driver 30 while output voltage U is low at the same time, gate driver 30 is only loaded by a low current across third resistor 31 and fourth resistor 32. Second Zener diode 28 and second resistor 24 are again used for overvoltage protection of freewheeling switching means 14.

The circuit described is preferably suited, for example, for use in a dual-voltage vehicle electrical system in a motor vehicle. However, it is not restricted to this application.

What is claimed is:

1. A device for voltage transformation of an input voltage into at least one output voltage, including at least one switching means (12), a freewheeling switching means (14), and an electrical energy accumulator (16, 18), the freewheeling switching means (14) being triggered in normal operation for voltage transformation,
wherein monitoring means (20, 22, 26, 31, 32, 36, 40) are provided for monitoring the output voltage (U) for exceeding a limit voltage which trigger the freewheeling switching means (14) in output voltage limiting operation if the limit voltage is exceeded, in order to limit the output voltage (U).

2. The device as recited in claim 1,
wherein at least one Zener diode (26, 36) and/or a transistor (40) is/are provided as monitoring means.

3. The device as recited in one of the preceding claims,
wherein, if the limit voltage is exceeded, the normal operation of at least the freewheeling switching means (14) and/or the switching means (12) is deactivated.

4. The device as recited in one of the preceding claims,
wherein overvoltage protection means (24, 28) are provided, which protect the freewheeling switching means (14) from overvoltages.

5. The device as recited in one of the preceding claims,
wherein a measure of the output voltage (U) is fed to a Zener diode (26), the Zener diode being electrically conductively connected to at least one control input of the freewheeling switching means (14) and/or of a transistor (40).

6. The device as recited in one of the preceding claims,
wherein the transistor (40) triggers the freewheeling switching means (14).

7. The device as recited in one of the preceding claims,
wherein the freewheeling switching means (14) is connected to a reference potential (8).

8. The device as recited in one of the preceding claims,
wherein, in output voltage limiting operation, the freewheling switching means (14) connects the input potential of the freewheeling switching means (14) to the reference potential (8).

9. The device as recited in one of the preceding claims,
characterized by a preferred use in a multi-voltage vehicle electrical system of a motor vehicle.
